(19) United States
(12) Patent Application Publication
(10) Pub. No.: US 2024/0189932 A1
(43) Pub. Date: Jun. 13, 2024

(54) SMART DESOLDERING DEVICE AND METHOD FOR LASER REMOVAL OF SUBSTRATE SOLDER MASK DRIVEN BY ARTIFICIAL INTELLIGENCE

(71) Applicants: Pei-Chung Pang, Taoyuan City (TW); Trillion Harvest Limited, The Valley (AI)

(72) Inventor: Pei-Chung PANG, Taoyuan City (TW)

(21) Appl. No.: 18/509,266

(22) Filed: Nov. 14, 2023

Related U.S. Application Data
(63) Continuation-in-part of application No. 18/076,914, filed on Dec. 7, 2022.

(51) Int. Cl. B23K 3/08; B23K 1/018; B23K 3/02; B23K 3/047; G05B 13/02; G05B 13/04

(52) U.S. Cl. CPC B23K 3/08; B23K 1/018; B23K 3/029; B23K 3/047; G05B 13/0265; G05B 13/042

(57) ABSTRACT

The invention discloses a smart desoldering device and method for laser removal of substrate solder mask driven by artificial intelligence. The smart desoldering device includes an artificial intelligence (AI) system including a database unit, a learning and training unit, a parameter optimization setting unit, a condition restriction unit and an AI model processing unit, a control processing module, a camera module and a laser desoldering module. The artificial intelligence (AI) system is used to learn and pre-train the types, sizes and thicknesses of substrates, the colors and thickness of solder mask and the depth around solder pads, and automatically optimize and set all processing parameters according to the characteristics of the substrate to be processed. The artificial intelligence (AI) system controls the laser desoldering module to perform laser desoldering on the substrate according to the first control command and a circuit layout diagram.

### BACKGROUND OF THE INVENTION

### 1. Field of the Invention

The present invention relates to a substrate desoldering device, and in particular, to a smart desoldering device and method for laser removal of substrate solder mask driven by artificial intelligence.

### 2. Description of the Related Art

In the general solder mask process of circuit substrates, after the printed circuit is set up, photosensitive solder resist is applied to the surface of the circuit substrate to form a solder mask, and is pre-baked until semi-cured. Then use a photomask for exposure and development technology, so that the solder mask is solidified on the parts of the circuit other than the solder pads. Then remove the uncured portion of the solder mask to expose the solder pads to the solder mask. Due to the necessary errors caused by exposure energy and development, the accuracy is limited, and the distance (pitch) between neighboring solder pads cannot be reduced. There is also the introduction of direct imaging technology, which reduces the cost of photomask, but the equipment cost is extremely high, and the same problem is faced technically.

However, the circuit substrate and photomask will be affected by environmental conditions such as temperature and humidity in the exposure part of the exposure device, causing changes in the positional accuracy of the positioning marks on the circuit substrate and the photomask and the positional accuracy of the exposure pattern. There will be a problem of being unable to form a high-precision pattern, causing the solder pads to be unable to correctly expose the solder mask. Furthermore, for circuit substrates with different solder pad positions, a photomask that conforms to the circuit substrate must be produced first, which increases the production cost of the circuit substrate.

In addition, the solder mask process of general circuit substrates often requires the use of different inks, making the ink costs high. Moreover, the semi-cured solder mask has insufficient hardness or is sticky, which can easily lead to scrapping during operation.

### SUMMARY OF THE INVENTION

The object of the present invention is to provide a smart desoldering device and method for laser removal of substrate solder mask driven by artificial intelligence.

The present invention provides a smart desoldering device for laser removal of substrate solder mask driven by artificial intelligence, which is used to process at least one substrate placed in a laser processing machine through an energy controllable laser, wherein each substrate corresponds to a panel production part number, and the surface of each substrate is provided with at least one solder pad, and a solder mask covers the surface of each substrate and the surface of the at least one solder pad of each substrate, and the solder mask has a shielding part facing the substrate surface and a clearing part facing the at least one solder pad. The smart desoldering device comprises an artificial intelligence (AI) system, a control processing module, a camera module and a laser desoldering module. The artificial intelligence (AI) system comprises a database unit, a learning and training unit, a parameter optimization setting unit, a condition restriction unit and an AI model processing unit. The artificial intelligence system is used to learn and pre-train the type of the at least one substrate, the size of the at least one substrate, the thickness of the at least one substrate, the color of the solder mask, the thickness of the solder mask and the depth around the at least one solder pad, and optimize and set all processing parameters automatically according to the characteristics of the at least one substrate to be processed. The database unit has relevant information on the type of the at least one substrate, the size of the at least one substrate, the thickness of the at least one substrate, the color of the solder mask, the thickness of the solder mask and the depth around the at least one solder pad. The database unit is connected to the Internet NT through a wireless network unit to update relevant data online. The learning and training unit being connected to said database unit. The learning and training unit performs learns and pre-trains through a substrate deep learning algorithm and based on relevant data in the database unit. The parameter optimization setting unit is connected to the database unit. The parameter optimization setting unit is used to optimize the processing parameters according to the relevant information on the type of the at least one substrate, the size of the at least one substrate, the thickness of the at least one substrate, the color of the solder mask, the thickness of the solder mask and the depth around the at least one solder pad. The condition restriction unit is connected to the learning and training unit. The condition restriction unit is used to limit the learning bias of the artificial intelligence system by setting multiple conditions. The AI model processing unit is connected to the learning and training unit and the parameter optimization setting unit. The AI model processing unit is used to learn and train an AI model through the learning and training unit. The AI model processing unit is the AI brain of said artificial intelligence system. The control processing module is connected to the AI model processing unit of the artificial intelligence system. The control processing module generates a first control command, a second control command and a third control command according to the instructions and related data sent by the AI model processing unit to perform processing operations on the at least one substrate. The camera module is connected to the control processing module. The camera module takes photos or images of the at least one substrate according to the first control command sent by the control processing module. The camera module reads the quick response matrix pattern of the panel production part number on the at least one substrate, and sends the quick response matrix pattern back to the AI model processing unit to identify the characteristics of the at least one substrate and carries out pre-processing preparations for parameter optimization settings. The laser desoldering module is connected to the control processing module, said laser desoldering module performing laser desoldering on the at least one substrate according to the first control command and a circuit layout diagram sent by the control processing module. The laser desoldering module uses a laser beam to peel off the clearing part according to a construction pattern, so that the solder mask forms at least one hollow part. The circuit layout diagram imports the data of the solder mask, and then converts the data of the solder mask into a positive image, a negative image or a graphic conversion process to obtain the construction pattern.

The present invention provides a smart desoldering method for laser removal of substrate solder mask driven by artificial intelligence, which is used to process at least one substrate placed in a laser processing machine through an energy controllable laser, wherein each substrate corresponds to a panel production part number, and desoldering is performed through a smart desoldering device. The smart desoldering device comprises an artificial intelligence system, a control processing module, a camera module, a laser desoldering module and an alignment module. The artificial intelligence system comprises a database unit, a learning and training unit, a parameter optimization setting unit, a condition restriction unit and an AI model processing unit. The learning and training unit is connected to the database unit. The parameter optimization setting unit is connected to the database unit. The condition restriction unit is connected to the learning and training unit. The AI model processing unit is connected to the learning and training unit and the parameter optimization setting unit. The control processing module is connected to the AI model processing unit of the artificial intelligence system. The camera module is connected to the control processing module. The laser desoldering module is connected to the control processing module. The alignment module is connected to the control processing module. The smart desoldering method for laser removal of substrate solder mask driven by artificial intelligence comprises the steps of:

Step S501: Set multiple conditions through the condition restriction unit to limit the learning bias of the artificial intelligence (AI) system.

Step S502: Through the learning and training unit, perform learning and pre-training according to a substrate deep learning algorithm and based on relevant data in the database unit, which has relevant information on types of substrates, sizes of substrates, thicknesses of substrates, colors of solder mask, thickness of solder mask and depth around solder pads.

Step S503: The AI model processing unit learns and trains an AI model through the learning and training unit, where the AI model processing unit is the AI brain of the artificial intelligence system.

Step S504: Provide a substrate with a solder pad on the surface of the substrate.

Step S505: Cover the surface of the substrate and the solder pad with a solder mask, where the solder mask has a shielding part facing the surface of the substrate, and a clearing part facing the solder pad.

Step S506: The alignment module uses an infrared light to align the substrate to be processed to further adjust the expansion and contraction of the construction pattern, where the infrared light is used to see through the solder mask, and the artificial intelligence (AI) system analyzes and eliminates unsuitable alignment point images, and calculates the deformation direction and degree of the substrate.

Step S507: Read the quick response matrix pattern of the panel production part number on the substrate through the camera module, and send it back to the AI model processing unit to identify the characteristics of the substrate, and perform pre-processing preparations for parameter optimization settings.

Step S508: Through the parameter optimization setting unit, perform optimized settings of multiple processing parameters according to the relevant information of the type of the substrate, the size of the substrate, the thickness of the substrate, the color of the solder mask, the thickness of the solder mask and the depth around the solder pad.

Step S509: The laser desoldering module performs laser desoldering on the substrate according to a first control command and a circuit layout diagram sent by the control processing module.

Step S510: Use a laser beam to peel off the clearing part according to a construction pattern, so that the solder mask forms at least one hollow part, in which the circuit layout diagram imports the data of the solder mask, and then the data of the solder mask is converted into positive images, negative images or graphics to obtain the construction pattern.

Step S511: Photograph the substrate through the camera module and take out a substrate processing picture.

Step S512: Compare and determine whether the substrate processing picture and the circuit layout diagram are the same.

Step S513: If the substrate processing picture and the circuit layout diagram are the same, complete the substrate processing operation.

Step S514: If the substrate processing picture and the circuit layout diagram are not the same, the laser beam peels off the clearing part based on the differences.

### BRIEF DESCRIPTION OF THE DRAWINGS

FIG. 1 is the architecture diagram of a smart desoldering device driven by artificial intelligence that uses laser to remove the solder mask of the substrate.

FIG. 2 is a side view of the substrate of the present invention.

FIG. 3 is a side view of the substrate covered with a solder mask of the present invention.

FIG. 4 is a schematic diagram of a substrate with multiple positioning points according to the first embodiment of the present invention.

FIG. 5 is a schematic diagram of a substrate with multiple positioning points according to the second embodiment of the present invention.

FIG. 6 is a three-dimensional schematic diagram of the smart desoldering device of the present invention processing a substrate.

FIG. 7 is a schematic diagram of the camera module of the present invention capturing images of a substrate.

FIG. 8 is a schematic diagram comparing the circuit layout diagram and the substrate processing picture of the present invention.

FIG. 9 is a schematic diagram of translating a laser dot matrix pattern according to the present invention.

FIG. 10 is a schematic diagram of the multi-light source laser processing of the substrate according to the present invention.

FIGS. 11 and 12 are flow charts of the smart desoldering method for laser removal of substrate solder mask driven by artificial intelligence according to the present invention.

### DETAILED DESCRIPTION OF THE PREFERRED EMBODIMENT

In order to solve many problems in the solder mask process of existing circuit substrates, the inventor has spent many years of research and development to improve the criticisms of existing products. The following will introduce in detail how the present invention uses a smart desoldering device and method for laser removal of substrate solder mask driven by artificial intelligence to achieve the most efficient functional requirements. Furthermore, the content of the present invention is to avoid the development defects caused by the traditional chemical process, and the traditional laser ablation to produce carbon residue due to thermal effects, which must be reprocessed or directly lead to scrapping.

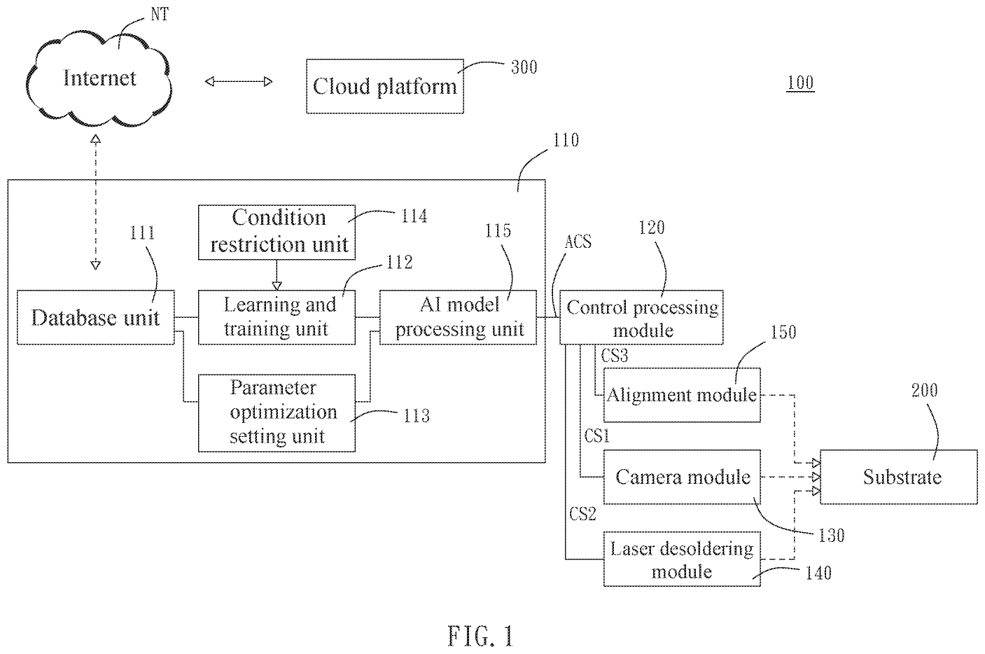

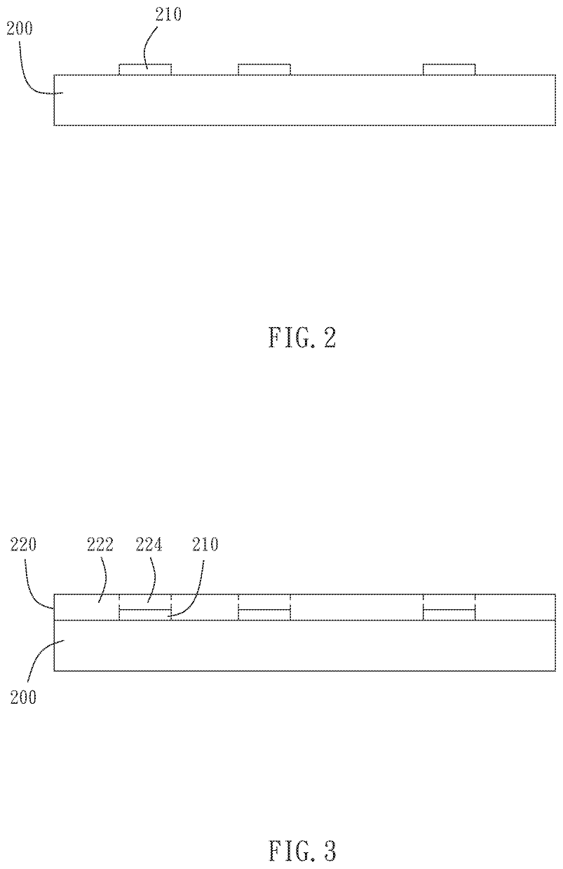

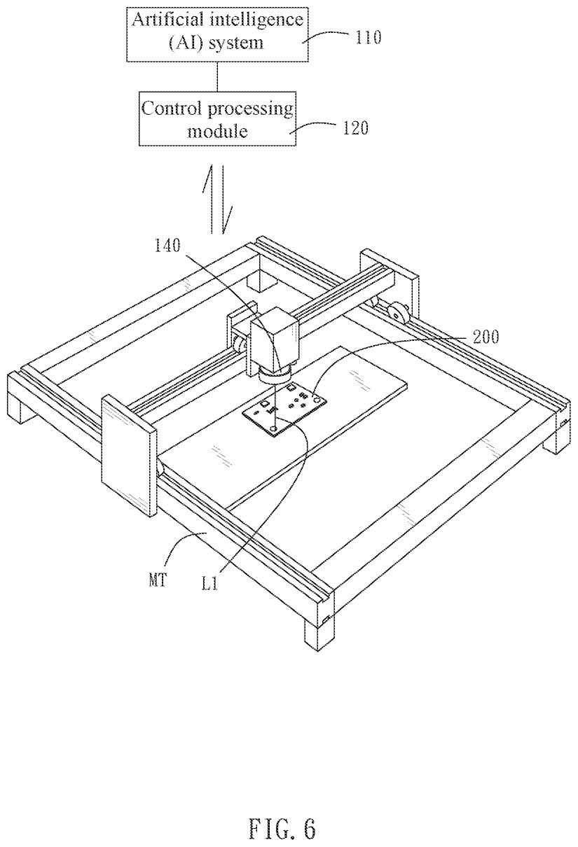

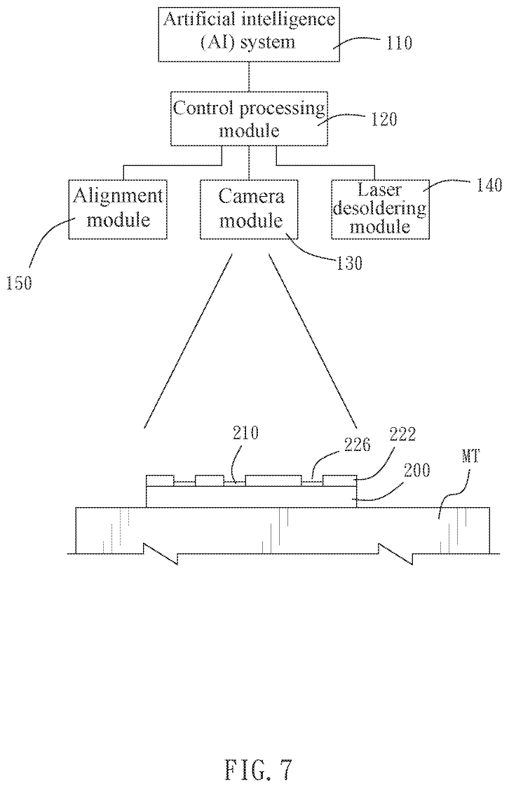

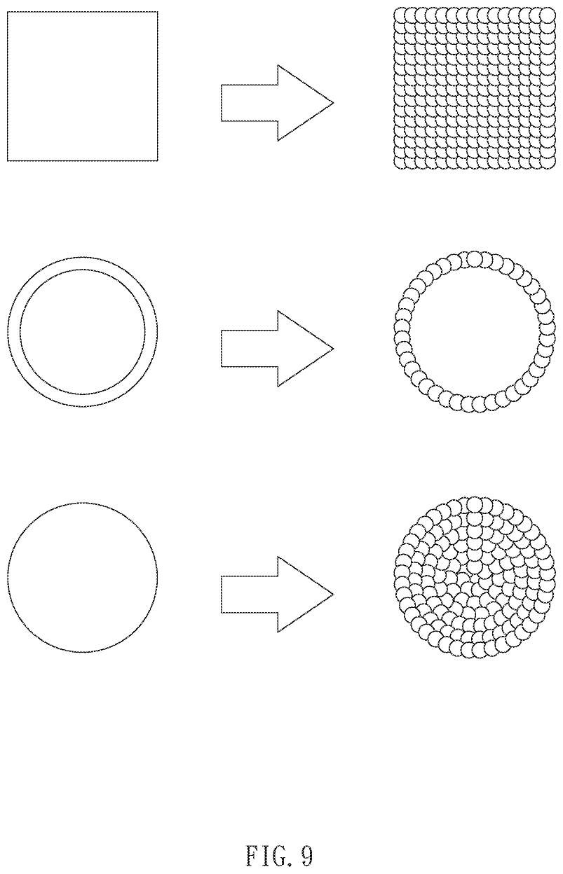

Please refer to FIGS. 1 to 3, 6, 7, and 9 at the same time, where FIG. 1 is the architecture diagram of a smart desoldering device driven by artificial intelligence that uses laser to remove the solder mask of the substrate, FIG. 2 is a side view of the substrate of the present invention, FIG. 3 is a side view of the substrate covered with a solder mask of the present invention, FIG. 6 is a three-dimensional schematic diagram of the smart desoldering device of the present invention processing a substrate, FIG. 7 is a schematic diagram of the camera module of the present invention capturing images of a substrate, and FIG. 9 is a schematic diagram of translating a laser dot matrix pattern according to the present invention.

As shown in FIG. 1, an artificial intelligence-driven smart desoldering device 100 for laser removal of substrate solder mask uses a laser with controllable energy to process all or part of a substrate, rather than just manually using lasers to optimize local or single points of the circuit substrate.In the embodiment of the present invention, the artificial intelligence-driven smart desoldering device 100 mainly uses artificial intelligence driven laser to remove the solder mask of the substrate to replace the complicated process in the existing technology and reduce environmental pollution, which complies with ESG standards. ESG is the abbreviation for environmental protection (E, Environmental), social responsibility (S, Social) and corporate governance (G, governance).

As shown in the figures, the smart desoldering device 100 of the present invention that uses artificial intelligence-driven laser to remove the solder mask of a substrate uses a laser with controllable energy to process at least one substrate 200 placed on a laser processing machine MT. Each substrate 200 corresponds to a panel production part number, and at least one solder pad 210 is provided on the surface of the substrate 200 and a solder mask 220 (such as green paint) is covered on the surface of the substrate 200 and the at least one solder pad 210. The solder mask 220 has a shielding part 222 facing the surface of the substrate 200, and the solder mask 220 has a clearing part 224 facing the at least one solder pad 210. Specifically, the smart desoldering device 100 for laser removal of substrate solder mask driven by artificial intelligence comprises an artificial intelligence (AI) system 110, a control processing module 120, a camera module 130 and a laser desoldering module 140. The artificial intelligence system 110 comprises a database unit 111, a learning and training unit 112, a parameter optimization setting unit 113, a condition restriction unit 114 and an AI model processing unit 115. The artificial intelligence (AI) system 110 is mainly used tolearn and pre-train the type of the substrate 200, the size of the substrate 200, the thickness of the substrate 200, the color of the solder mask 220, the thickness of the solder mask 220 and the depth around the solder pads 210, and optimize and set all processing parameters automatically according to the characteristics of the substrate 200 to be processed. The database unit 111 has relevant information on the types of the substrates 200, the sizes of the substrates 200, the thicknesses of the substrates 200, the colors of the solder mask 220, the thickness of the solder mask 220 and the depth around the solder pads 210. The database unit 111 is connected to the Internet NT through a wireless network unit (not shown) and further connected to a cloud platform 300 to update relevant data online or substrate deep learning algorithms (for use by the learning and training unit 112).

Furthermore, the learning and training unit 112 is connected to the database unit 111. The learning and training unit 112 performs learning and pre-training through the substrate deep learning algorithm and based on the relevant data in the database unit 111 to identify which processing parameter settings are required for different substrate characteristics for laser desoldering. The parameter optimization setting unit 113 is connected to the database unit 111. The parameter optimization setting unit 113 is used to perform optimized settings of multiple processing parameters according to the relevant information of the types of the substrates 200, the sizes of the substrates 200, the thicknesses of the substrates 200, the colors of the solder mask 220, the thickness of the solder mask 220 and the depth around the solder pads 210. The condition restriction unit 114 is connected to the learning and training unit 112. The condition restriction unit 114 is used to limit the learning bias or operational misunderstanding of the artificial intelligence (AI) system by setting multiple conditions. The designer can introduce at least one condition to the condition restriction unit 114 according to actual needs. The AI model processing unit 115 is connected to the learning and training unit 112 and the parameter optimization setting unit 113. The AI model processing unit 115 uses the learning and training unit 112 to learn and train the AI model. The AI model processing unit 115 is the AI brain of the artificial intelligence system 110. At this time, the AI model processing unit 115 has been pre-trained by numerous data or large data of practical operations, so, optimal settings can be given based on different substrate characteristics. Therefore, before any operation or any process parameter input, it must first go through the analysis, judgment and decision-making of the AI model processing unit 115 to avoid manual input errors or back-end laser equipment operation errors.

Furthermore, in the present invention, the control processing module 120 is connected to the AI model processing unit 115 of the artificial intelligence system 110. The control processing module 120 generates a first control command CS1, a second control command CS2 and a third control command CS3 according to the smart control command ACS and related data sent by the AI model processing unit 115 to perform processing operations on the substrate 200. It should be noted that the smart control command ACS includes multiple processing parameters calculated and optimized by the AI model processing unit 115, as well as the best construction paths and construction rules. In other words, the AI model processing unit 115 will instruct the control processing module 120 to control all operations of the camera module 130, laser desoldering module 140 and alignment module 150. The camera module 130 is connected to the control processing module 120. The camera module 130 takes photos or images of the substrate 200 according to the first control command CS1 sent by the control processing module 120. The control processing module 120 will take pictures of the substrate 200 through the camera module 130 and take out the substrate processing pictures. The number of camera module 130 is not limited to one. The camera module 130 can photograph one of the units or processed areas of the substrate 200 and take out pictures, or it canphotograph the entire substrate 200 and take out pictures. This will be done according to preset rules. Furthermore, the camera module 130 reads the quick response matrix pattern of the panel production part number on the substrate 200 and sends it back to the AI model processing unit 115 to identify the characteristics of the substrate 200 and carry out pre-processing preparations for parameter optimization settings.

The laser desoldering module 140 is connected to the control processing module 120. The laser desoldering module 140 performs laser desoldering on the substrate 200 according to the first control command CS1 and a circuit layout diagram TA transmitted by the control processing module 120, and divides the substrate 200 into multiple areas to be processed through the circuit layout diagram TA. The laser beam then performs a stripping operation on the clearing part 224 of each of the areas to be processed according to a preset rule. The circuit layout diagram TA mentioned above is produced through a computer-aided design (CAD)/computer-aided manufacturing (CAM) system. This is a system for automatic design, first draft, and presentation. Graphically guided automation system. This is a graphically guided automated system for automated design, drafting, and presentation.

Furthermore, before officially performing laser desoldering on the substrate 200, the operator will import the process parameters, such as ink type, color, thickness, moving area or other parameter values, to let the AI model processing unit 115 of the artificial intelligence system 110 calculate the required laser spot size and number of laser shots, so as to achieve optimal results. Because the AI model processing unit 115 has been pre-trained by a large number of data or large data from practical operations, it can provide optimized settings based on different substrate characteristics. Next, the laser desoldering module 140 uses a laser beam L1 to peel off the clearing part 221 on the substrate 200 according to a construction pattern, so that the solder mask 220 forms at least one hollow part 226.

The circuit layout diagram TA imports the data of the solder mask 220, and then converts the data of the solder mask 220 into a positive image, a negative image or a graphics conversion process to obtain the construction pattern. In the present invention, after obtaining the construction pattern, the control processing module 120 calculates the overlapping area size of the laser spots based on the laser spot size and energy of the laser desoldering module 140, and then translates a laser dot matrix pattern, as shown in FIG. 9. In FIG. 9, the translation of three graphics is used to illustrate, and the resolution of the laser dot matrix pattern can be set by the designer or operator.

It should be noted that the laser emitted by the laser beam L1 is a high-frequency laser beam of milliseconds or above (milliseconds, microseconds, nanoseconds or picoseconds). The type of laser beam L1 depends on the characteristics of the material and uses at least one of carbon dioxide (CO2) laser, Yag laser, green laser and ultraviolet light to achieve the effect of removing solder mask without residue or carbonization. In the embodiment of the present invention, for example, the laser beam L1 is a picosecond laser beam, and the picosecond laser beam stays on the substrate 200 for a very short time, that is, it will not excessively ablate or remove the solder pad 210 under the solder mask 220.

In addition, the artificial intelligence (AI) system 110 in the present invention will predict or adjust the size and shape of the laser spot based on the processing path, the construction pattern and the amount of energy required by the material.Furthermore, the artificial intelligence (AI) system 110 uses the parameter optimization setting unit 113 according to the calculation results to adjust different laser spot sizes and different number of laser shots in different areas of the same board of the substrate 200 to achieve the goal of vaporizing the surface.

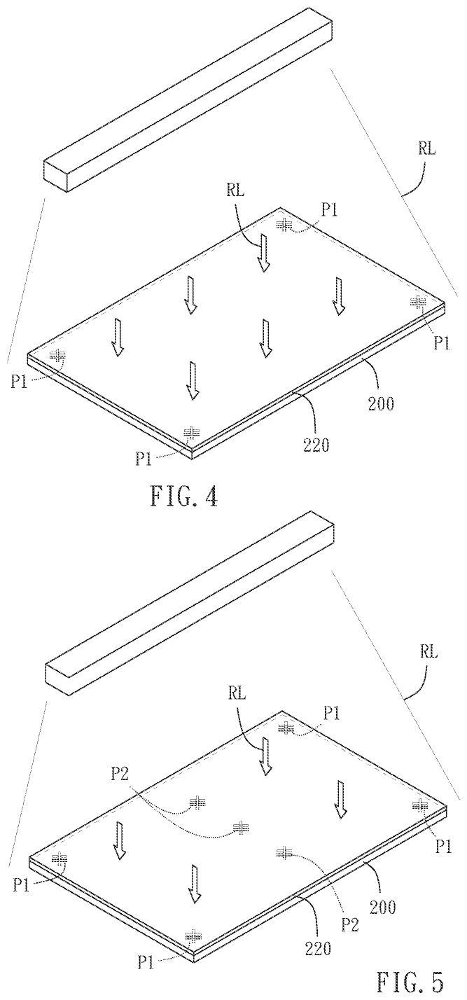

Please refer to FIGS. 1 to 5 at the same time, where FIG. 4 is a schematic diagram of a substrate with multiple positioning points according to the first embodiment of the present invention and FIG. 5 is a schematic diagram of a substrate with multiple positioning points according to the second embodiment of the present invention. Before laser processing, the substrate 200 is usually flattened and aligned. How the present invention performs alignment will be further described below, and substrate planarization will not be described in detail here. Under the existing technology, the positioning pins on the workbench and the positioning sleeve on the panel only have a positioning function and are not capable of solving the problem of deformation, expansion and contraction of the panel, so the panel is often scrapped. However, the present invention can solve such problems, which will be described in detail below. As shown in FIG. 4, in one embodiment, the four corners around the substrate 200 have an alignment pointP1respectively. In another embodiment, the four corners around the substrate 200 have an alignment point P1 respectively, and the central region of the substrate has at least two alignment points P2, as shown in FIG. 5. The artificial intelligence-driven smart desoldering device 100 for laser removal of substrate solder mask of the present invention also comprises an alignment module 150. The alignment module 150 is connected to the control processing module 120. The alignment module 150 aligns the substrate 200 to be processed according to a third control command CS3 transmitted by the control processing module 120 and through an infrared light RL to further adjust the expansion and contraction range of the construction pattern. Furthermore, because the solder mask 220 will cover the alignment point P1 or P2, using the characteristics of infrared light RL to penetrate organic matter, the infrared light RL needs to be used to see through the solder mask 220 in order to accurately collect the image of the alignment point P1 or P2. The artificial intelligence (AI) system 110 can be used to analyze and eliminate unsuitable alignment point P1 or P2 images, and then perform alignment. After the alignment is completed, the artificial intelligence (AI) system 110 calculates the direction and degree of deformation of the substrate 200, that is, the expansion and contraction deformation will be adjusted according to the actual object. Next, CAM (Computer Aided Manufacturing) is used to generate the deformed output construction pattern.

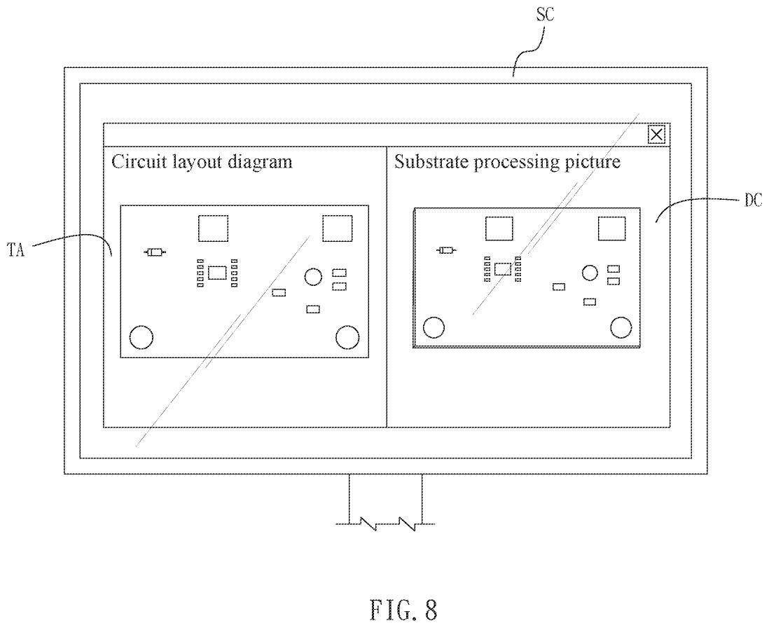

Next, please refer to FIGS. 1 to 8 at the same time, where FIG. 8 is a schematic diagram comparing the circuit layout diagram and the substrate processing picture of the present invention. After the laser desoldering module 140 passes a laser beam L1 and performs a stripping operation on the clearing part 221 on the substrate 200 according to a construction pattern, the control processing module 120 will control the camera module 130 to take pictures of the substrate 200 and take out a substrate processing picture DC, and compare and determine whether the substrate processing picture DC and the circuit layout diagram TA are the same. On the screen SC in FIG. 8, you can see that the substrate processing picture DC and the circuit layout diagram TA are being compared. If they are the same, the substrate processing operation is completed. If they are not the same, the laser desoldering module 140 will emit the laser beam L1 to remove the clearing part 224 based on the difference. According to this, since the artificial intelligence-driven smart desoldering device 100 for laser removal of substrate solder mask of the present invention does not use a photomask at all, the circuit substrate 200 with different solder pad 210 positions no longer needs to first produce a photomask that conforms to the circuit substrate. In addition, the artificial intelligence-driven smart desoldering device 100 for laser removal of substrate solder mask does not use an exposure device at all, so it will not be affected by environmental conditions such as temperature and humidity in the exposure part of the exposure device. Therefore, the positional accuracy of the circuit substrate and the positioning marks on the photomask and the positional accuracy of the exposure pattern will not be changed.

The above control processing module 120, camera module 130 and alignment module 140 can be regarded as a laser device.

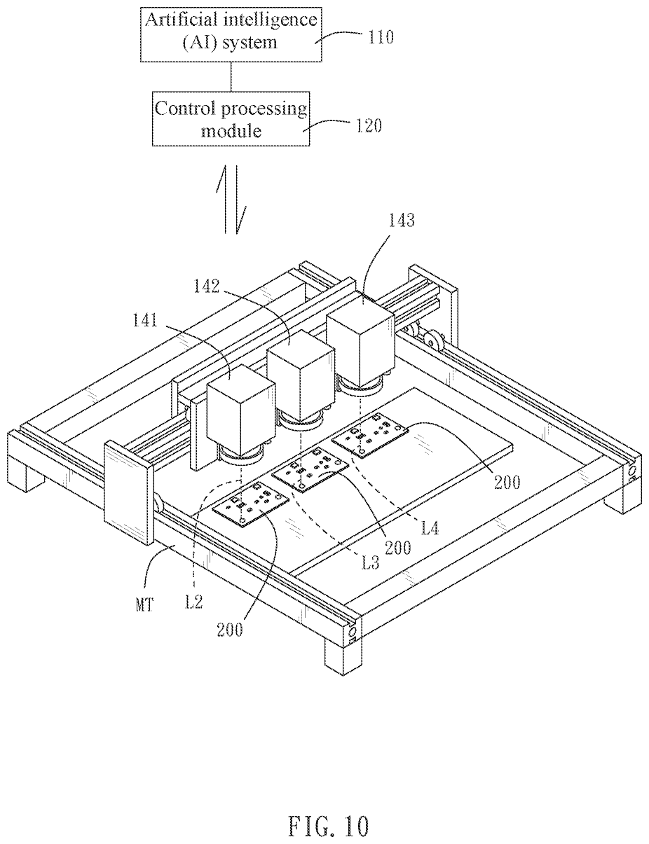

Finally, please refer to FIG. 1 and FIG. 10, where FIG. 10 is a schematic diagram of the multi-light source laser processing of the substrate according to the present invention. The laser processing machine MT has multiple laser desoldering modules 141, 142 and 143, which are the same as the laser desoldering module 140 in FIG. 1. The laser desoldering modules 141, 142 and 143 are respectively connected to the control processing module 120 to perform multi-tasking operations. In addition, the multiple laser desoldering modules 141, 142 and 143 respectively emit laser beams L2, L3 and L4 according to the circuit layout diagram TA and sequentially perform ablation or stripping operations on the clearing part 224 on the substrate 200. The laser light source of each laser desoldering module is responsible for a different area, which helps to further improve the efficiency of the processing process. In this embodiment, three laser desoldering modules 141, 142 and 143 are used as an example, but in practical applications, the number is not limited to three. The laser beams L2, L3 and L4 can be high-frequency laser beams above milliseconds (milliseconds, microseconds, nanoseconds or picoseconds).

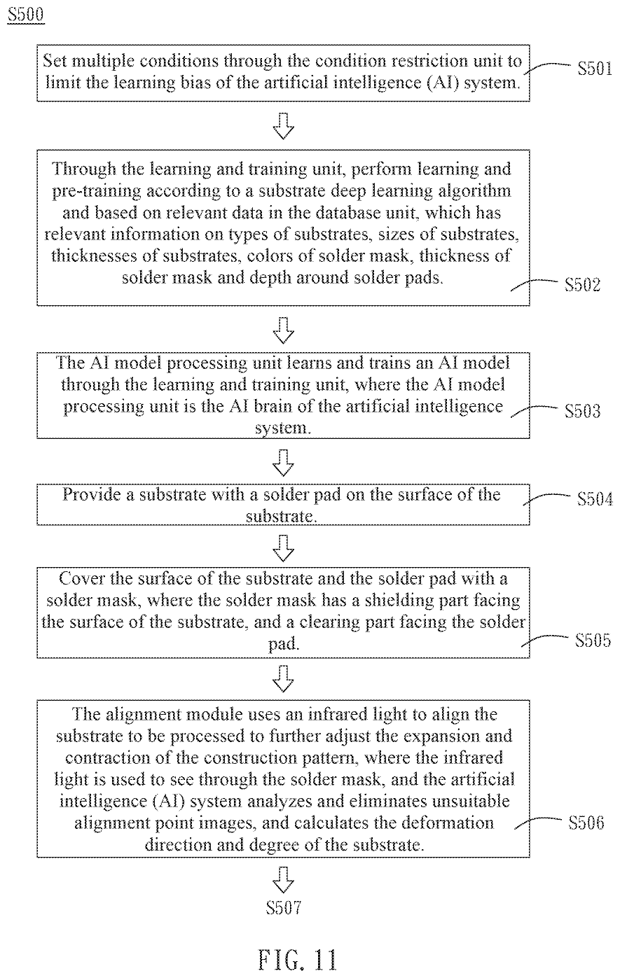

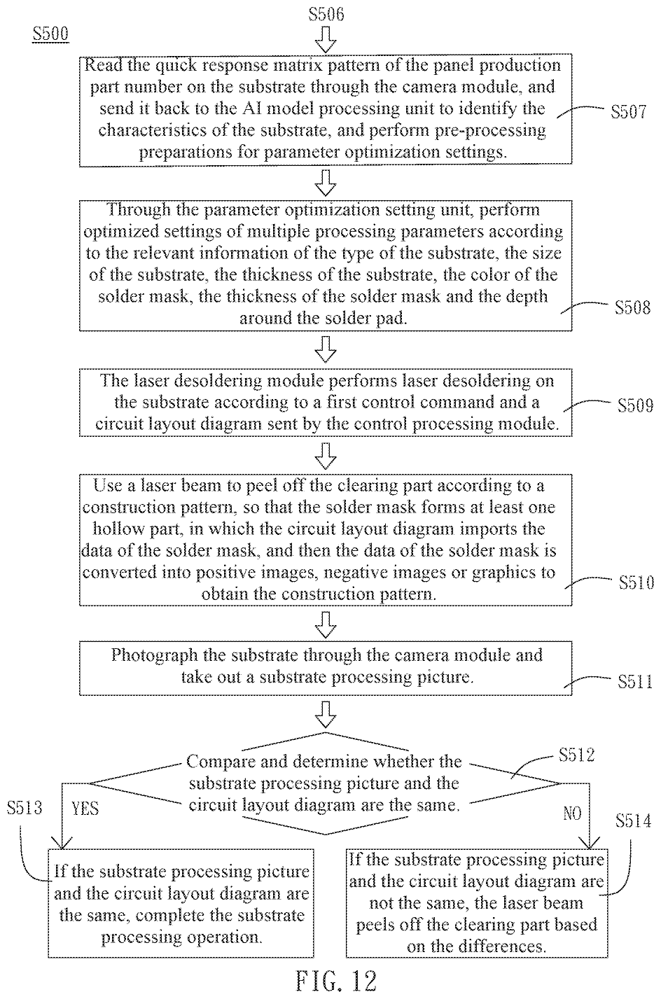

Next, please refer to FIGS. 11 and 12, which are flow charts of the smart desoldering method for laser removal of substrate solder mask driven by artificial intelligence according to the present invention. The smart desoldering method uses a laser with controllable energy to process at least one substrate placed in a laser processing machine. Each substrate corresponds to a panel production part number, and is desoldered by a smart desoldering device. The smart desoldering device comprises an artificial intelligence (AI) system, a control processing module, a camera module, a laser desoldering module and an alignment module. The artificial intelligence (AI) system comprises a database unit, a learning and training unit, a parameter optimization setting unit, a condition restriction unit and an AI model processing unit. The learning and training unit is connected to the database unit. The parameter optimization setting unit is connected to the database unit. The condition restriction unit is connected to the learning and training unit.The AI model processing unit is connected to the learning and training unit and the parameter optimization setting unit.The control processing module is connected to the AI model processing unit of the artificial intelligence system. The camera module is connected to the control processing module. The laser desoldering module is connected to the control processing module. The alignment module is connected to the control processing module. The smart desoldering method500for laser removal of substrate solder mask driven by artificial intelligence comprises the following steps:

Step S501: Set multiple conditions through the condition restriction unit to limit the learning bias of the artificial intelligence (AI) system.

Step S502: Through the learning and training unit, perform learning and pre-training according to a substrate deep learning algorithm and based on relevant data in the database unit, which has relevant information on types of substrates, sizes of substrates, thicknesses of substrates, colors of solder mask, thickness of solder mask and depth around solder pads.

Step S503: The AI model processing unit learns and trains an AI model through the learning and training unit, where the AI model processing unit is the AI brain of the artificial intelligence system.

Step S504: Provide a substrate with a solder pad on the surface of the substrate.

Step S505: Cover the surface of the substrate and the solder pad with a solder mask, where the solder mask has a shielding part facing the surface of the substrate, and a clearing part facing the solder pad.

Step S506: The alignment module uses an infrared light to align the substrate to be processed to further adjust the expansion and contraction of the construction pattern, where the infrared light is used to see through the solder mask, and the artificial intelligence (AI) system analyzes and eliminates unsuitable alignment point images, and calculates the deformation direction and degree of the substrate.

Step S507: Read the quick response matrix pattern of the panel production part number on the substrate through the camera module, and send it back to the AI model processing unit to identify the characteristics of the substrate, and perform pre-processing preparations for parameter optimization settings.

Step S508: Through the parameter optimization setting unit, perform optimized settings of multiple processing parameters according to the relevant information of the type of the substrate, the size of the substrate, the thickness of the substrate, the color of the solder mask, the thickness of the solder mask and the depth around the solder pad.

Step S509: The laser desoldering module performs laser desoldering on the substrate according to a first control command and a circuit layout diagram sent by the control processing module.

Step S510: Use a laser beam to peel off the clearing part according to a construction pattern, so that the solder mask forms at least one hollow part, in which the circuit layout diagram imports the data of the solder mask, and then the data of the solder mask is converted into positive images, negative images or graphics to obtain the construction pattern.

Step S511: Photograph the substrate through the camera module and take out a substrate processing picture.

Step S512: Compare and determine whether the substrate processing picture and the circuit layout diagram are the same.

Step S513: If the substrate processing picture and the circuit layout diagram are the same, complete the substrate processing operation.

Step S514: If the substrate processing picture and the circuit layout diagram are not the same, the laser beam peels off the clearing part based on the differences.

The rest of the operations are as described in the embodiments shown in FIGS. 1 to 8 above, and will not be described again here.

To sum up, the present invention can achieve the following effects:
1. Significantly shorten the steps of the processing process.
2. Improve process yield.
3. Laser beam with controllable energy.
4. Improve the pattern accuracy of the processing process.
5. For circuit substrates with different solder pad positions, it is no longer necessary to first create a photomask that matches the circuit substrate.
6. It will not be affected by environmental conditions such as temperature and humidity.
7. No development is required to significantly reduce wastewater pollution and save energy.
8. No ink limit, reducing ink costs.
9. Use at least one of carbon dioxide (CO₂) laser, Yag laser, green laser and ultraviolet light to achieve the effect of removing solder mask without residue or carbonization.
10. Solve the problem in the existing technology that the semi-cured solder mask has insufficient hardness or is sticky, which can easily cause scrapping during operation.

11. Reduce environmental harm, comply with ESG standards, and contribute to sustainable development.

What the invention claimed is:

1. A smart desoldering device for laser removal of substrate solder mask driven by artificial intelligence, which is used to process at least one substrate placed in a laser processing machine through an energy controllable laser, wherein each said substrate corresponds to a panel production part number, and the surface of each said substrate is provided with at least one solder pad, and a solder mask covers the surface of each said substrate and the surface of the at least one solder pad of each said substrate, and said solder mask has a shielding part facing the substrate surface and a clearing part facing said at least one solder pad, said smart desoldering device comprising:
an artificial intelligence system used to learn and pre-train the type of said at least one substrate, the size of said at least one substrate, the thickness of said at least one substrate, the color of said solder mask, the thickness of said solder mask and the depth around said at least one solder pad and optimize and set all processing parameters automatically according to the characteristics of the said at least one substrate to be processed, said artificial intelligence system comprising a database unit, a learning and training unit, a parameter optimization setting unit, a condition restriction unit and an AI model processing unit, said database unit having relevant information on the type of said at least one substrate, the size of said at least one substrate, the thickness of said at least one substrate, the color of said solder mask, the thickness of said solder mask and the depth around said at least one solder pad, said database unit being connected to the Internet NT through a wireless network unit to update relevant data online, said learning and training unit being connected to said database unit, said learning and training unit performing learning and pre-training through a substrate deep learning algorithm and based on relevant data in said database unit, said parameter optimization setting unit being connected to said database unit, said parameter optimization setting unit being used to optimize the processing parameters according to the relevant information on the type of said at least one substrate, the size of said at least one substrate, the thickness of said at least one substrate, the color of said solder mask, the thickness of said solder mask and the depth around said at least one solder pad, said condition restriction unit being connected to said learning and training unit, said condition restriction unit being used to limit the learning bias of said artificial intelligence system by setting multiple conditions, said AI model processing unit being connected to said learning and training unit and said parameter optimization setting unit, said AI model processing unit being the AI brain of said artificial intelligence system and being used to learn and train an AI model through said learning and training unit;
a control processing module being connected to said AI model processing unit of said artificial intelligence system, said control processing module generating a first control command, a second control command and a third control command according to the instructions and related data sent by said AI model processing unit to perform processing operations on said at least one substrate;
a camera module being connected to said control processing module, said camera module taking photos or images of said at least one substrate according to said first control command sent by said control processing module, said camera module reading the quick response matrix pattern of the panel production part number on said at least one substrate and sending the quick response matrix pattern back to said AI model processing unit to identify the characteristics of said at least one substrate and carrying out pre-processing preparations for parameter optimization settings; and
a laser desoldering module being connected to said control processing module, said laser desoldering module performing laser desoldering on said at least one substrate according to the first control command and a circuit layout diagram sent by said control processing module, said laser desoldering module using a laser beam to peel off said clearing part according to a construction pattern, so that said solder mask forms at least one hollow part, said circuit layout diagram importing the data of said solder mask, and then converting the data of said solder mask into a positive image, a negative image or a graphic conversion process to obtain said construction pattern.

2. The smart desoldering device for laser removal of substrate solder mask driven by artificial intelligence as claimed in claim 1, wherein said artificial intelligence system predicts or adjusts the size and shape of the laser spot based on the processing path, the construction pattern and the amount of energy required by the material.

3. The smart desoldering device for laser removal of substrate solder mask driven by artificial intelligence as claimed in claim 1, wherein said artificial intelligence system uses said parameter optimization setting unit according to the calculation results to adjust different laser spot sizes and different number of laser shots in different areas of the same board of the substrate.

4. The smart desoldering device for laser removal of substrate solder mask driven by artificial intelligence as claimed in claim 1, further comprising an alignment module connected to said control processing module, said The alignment module using an infrared light to align the substrate to be processed according to a third control command transmitted by said control processing module to further adjust the expansion and contraction range of said construction pattern, wherein said infrared light is used to see through said solder mask, wherein said artificial intelligence system analyzes and eliminates unsuitable alignment element point images, and calculates the deformation direction and degree of the substrate.

5. The smart desoldering device for laser removal of substrate solder mask driven by artificial intelligence as claimed in claim 4, wherein each said substrate comprises an alignment point at each of four corners thereof.

6. The smart desoldering device for laser removal of substrate solder mask driven by artificial intelligence as claimed in claim 4, wherein each said substrate comprises an alignment point in each of four corners thereof, and at least two alignment points in a central region thereof.

7. The smart desoldering device for laser removal of substrate solder mask driven by artificial intelligence as claimed in claim 1, wherein after obtaining said construction pattern, said control processing module calculates the overlapping area size of the laser spots based on the laser spot size and energy of said laser desoldering module, and then translates a laser dot matrix pattern.

8. The smart desoldering device for laser removal of substrate solder mask driven by artificial intelligence as claimed in claim 1, wherein said camera module photograph the substrate and take out a substrate processing picture, and compare and judge whether said substrate processing picture is the same as said circuit layout diagram, if said substrate processing picture and said circuit layout diagram are the same, the substrate processing operation is completed.

9. The smart desoldering device for laser removal of substrate solder mask driven by artificial intelligence as claimed in claim 8, wherein in the step of comparing and judging whether said substrate processing picture and said circuit layout diagram are the same, if said substrate processing picture and said circuit layout diagram are not the same, the laser beam will peel off said clearing part based on the differences.

10. The smart desoldering device for laser removal of substrate solder mask driven by artificial intelligence as claimed in claim 1, wherein the substrate is divided into multiple areas to be processed through said circuit layout diagram, and then the laser beam peels off said clearing part of each area to be processed according to a preset rule.

11. The smart desoldering device for laser removal of substrate solder mask driven by artificial intelligence as claimed in claim 1, wherein the laser emitted by the laser beam is a high-frequency laser beam of millisecond or above.

12. The smart desoldering device for laser removal of substrate solder mask driven by artificial intelligence as claimed in claim 1, wherein the type of the laser beam adopts at least one of carbon dioxide laser, chromium laser, green laser and ultraviolet light according to the characteristics of the material to achieve the effect of removing said solder mask without leaving any residue or carbonization.

13. The smart desoldering device for laser removal of substrate solder mask driven by artificial intelligence as claimed in claim 1, wherein said laser desoldering module comprises multiple sets of laser light sources to respectively emit the laser beam, which respectively performs the stripping operation on said clearing part of the substrate according to said first control command and said circuit layout diagram, in which each laser light source is responsible for a different area.

14. A smart desoldering method for laser removal of substrate solder mask driven by artificial intelligence, which is used to process at least one substrate placed in a laser processing machine through an energy controllable laser, wherein each said substrate corresponds to a panel production part number, and desoldering is performed through a smart desoldering device, said smart desoldering device comprising an artificial intelligence system, a control processing module, a camera module, a laser desoldering module and an alignment module, said artificial intelligence system comprising a database unit, a learning and training unit, a parameter optimization setting unit, a condition restriction unit and an AI model processing unit, said learning and training unit being connected to said database unit, said parameter optimization setting unit being connected to said database unit, said condition restriction unit being connected to said learning and training unit, said AI model processing unit being connected to said learning and training unit and said parameter optimization setting unit, said control processing module being connected to said AI model processing unit of said artificial intelligence system, said camera module being connected to said control processing module, said laser desoldering module being connected to said control processing module, said alignment module being connected to said control processing module, the smart desoldering method for laser removal of substrate solder mask driven by artificial intelligence comprising the steps of:
Step S501: setting multiple conditions through said condition restriction unit to limit the learning bias of said artificial intelligence (AI) system;
Step S502: through said learning and training unit, performing learning and pre-training according to a substrate deep learning algorithm and based on relevant data in said database unit, which has relevant information on types of substrates, sizes of substrates, thicknesses of substrates, colors of solder mask, thickness of solder mask and depth around solder pads;
Step S503: said AI model processing unit learning and training an AI model through said learning and training unit, where said AI model processing unit is the AI brain of said artificial intelligence system;
Step S504: providing a substrate with a solder pad on the surface of said substrate;
Step S505: covering the surface of said substrate and said solder pad with a solder mask, where said solder mask has a shielding part facing the surface of said substrate, and a clearing part facing said solder pad;
Step S506: said alignment module using an infrared light to align said substrate to be processed to further adjust the expansion and contraction of the construction pattern, where the infrared light is used to see through said solder mask, and said artificial intelligence (AI) system analyzes and eliminates unsuitable alignment point images, and calculates the deformation direction and degree of said substrate;
Step S507: reading the quick response matrix pattern of the panel production part number on said substrate through said camera module, and sending the read quick response matrix pattern back to said AI model processing unit to identify the characteristics of said substrate, and performing pre-processing preparations for parameter optimization settings;
Step S508: through said parameter optimization setting unit, performing optimized settings of multiple processing parameters according to the relevant information of the type of said substrate, the size of said substrate, the thickness of said substrate, the color of said solder mask, the thickness of said solder mask and the depth around said solder pad;
Step S509: said laser desoldering module performing laser desoldering on said substrate according to a first control command and a circuit layout diagram sent by said control processing module.
Step S510: using a laser beam to peel off said clearing part according to a construction pattern, so that said solder mask forms at least one hollow part, in which said circuit layout diagram imports the data of said solder mask, and then the data of said solder mask is converted into positive images, negative images or graphics to obtain the construction pattern.
Step S511: photographing said substrate through said camera module and taking out a substrate processing picture;
Step S512: comparing and determining whether said substrate processing picture and said circuit layout diagram are the same.
Step S513: completing the substrate processing operation if said substrate processing picture and said circuit layout diagram are the same; and
Step S514: said laser beam peeling off said clearing part based on the differences if said substrate processing picture and said circuit layout diagram are not the same.

15. The smart desoldering method for laser removal of substrate solder mask driven by artificial intelligence as claimed in claim 14, wherein said artificial intelligence system uses said parameter optimization setting unit according to the calculation results to adjust different laser spot sizes and different number of laser shots in different areas of the same board of said substrate, and said artificial intelligence system predicts or adjusts the size and shape of the laser spot based on the processing path, the construction pattern and the energy required by the material.
